(19) United States
(12) Patent Application Publication
(10) Pub. No.: US 2010/0147375 A1
(43) Pub. Date: Jun. 17, 2010

(54) MICRO-CONCENTRATORS FOR SOLAR CELLS

(75) Inventors: Omer Korech, Rishon-LeZion (IL); Jeffrey Gordon, Midreshet Ben-Gurion (IL); Ivgeny Katz, Beer-Sheva (IL); Daniel Feuermann, Midreshet Ben-Gurion (IL); Naftali P. Eisenberg, Jerusalem (IL)

Correspondence Address: MARTIN D. MOYNIHAN d/b/a PRTSI, INC., P.O. BOX 16446, ARLINGTON, VA, 22215, US

(73) Assignees: Ben Gurion University of the Negev Research and Development Authority, Beer-Sheva (IL); Naftali P. Eisenberg, Jerusalem (IL)

(21) Appl. No.: 12/527,696

(22) PCT Filed: Feb. 18, 2008
(86) PCT No.: PCT/IL08/00210

§ 371 Date: Jan. 7, 2010

(30) Foreign Application Priority Data
Feb. 22, 2007 (IL) 181517

(51) Int. Cl. H01L 31/00

(52) U.S. Cl. 136/256; 136/252; 136/259

(57) ABSTRACT

A solar cell system comprises a solar cell comprising a grid and a photo-sensitive area, wherein the grid includes a conductor, and an optical micro-structure positioned between the conductors, wherein the micro-structure covers at least a portion of the conductors.

### FIELD OF THE INVENTION

The present invention relates to optical systems for solar cells.

### BACKGROUND OF THE INVENTION

Solar cell devices convert light energy into electrical energy through the photovoltaic (PV) effect. Concentrator solar cells include a macro-concentrator to direct and focus the surrounding light onto the solar cell. Known macro-concentrators typically include Fresnel lenses and single- or multiple-mirrored systems. By intensifying the light energy reaching the photovoltaics, the quantity of solar cells required may be reduced, for example, by the amount of concentration provided by the concentrator, and solar cell efficiency may be increased.

Solar cells typically include a photo-sensitive area to absorb light energy over which a metal grid and/or conductor e.g. metal fingers, is embedded to collect and conduct the converted electrical current. Naturally, the positioning of the metal grid over the photo-sensitive area obstructs a portion of the photo-sensitive area over which the metal fingers are embedded and reduces the potential area over which light energy may be absorbed and the efficiency of the solar cells. In addition, shadows of the embedded grid leads to obstruction of photo-sensitive areas neighboring the metal fingers, further reducing the efficiency of the solar cells. The optimal metal grid coverage of solar cell surfaces usually reflects the tradeoff between shading obscuration and the cell's series resistance.

Known solutions may include prismatic and micro-lens covers that sit over the solar cell and metal fingers and direct light to a photo-sensitive area between the metal fingers. Also known are contoured metal fingers that include angled smooth surfaces to reflect light off the metal surfaces toward the photo-sensitive area.

Known prismatic and micro-lens covers, as well as contoured metal fingers that nominally mitigate this shadowing may be restricted by absorptive losses of the covers, contour precision, Fresnel reflections at added air-dielectric interfaces, and/or optical aberrations for the sizable angular range of cell irradiation typical to PV concentrators. A known back-contact strategy may be viable for silicon technology but may be precluded for known ultra-efficient solar cells e.g., based on III-V semiconductors.

### SUMMARY OF THE INVENTION

An aspect of some embodiments of the invention is the provision of an optical micro-structure positioned on the face of a solar cell to redirect impinging light directed toward the metal fingers and/or conductors, towards photo-sensitive areas, e.g. photo-sensitive areas between metal fingers. The micro-structure includes a top surface through which impinging light is collected and a respective bottom surface that is structured to fit over a photo-sensitive area between metal fingers, to which the collected light is directed. Optionally, the structure is tapered from a larger area above the metal fingers, to a smaller area between the metal fingers and over the photo-sensitive surface.

In one example, the micro-structure is a dielectric micro-concentrator including a non-imaging micro-structure based on substantially total internal reflection.

In some embodiments of the present invention, the micro-concentrator is sandwiched between a solar cell and a macro-concentrator and is optically coupled to both of them. For example, the micro-concentrator may be in physical contact with the macro-concentrator. In one example, the micro-concentrator is fabricated from a material having an index of refraction (n) comparable to the macro-concentrator. In another example, the micro-concentrator is fabricated from a material having an n comparable to an anti-reflective coating on the solar cell. In another example, when the macro-concentrator is a lens or is otherwise not in physical or optical contact with the micro-concentrator or cell, the micro-concentrator is still fabricated from a material having an n comparable to an anti-reflective coating on the solar cell, or would itself have an entry with an anti-reflective coating. In other examples the macro-concentrator may include a mirror.

According to another embodiment of the present invention, the micro-structure may be configured to accept all rays over a first, input, angular range, and concentrate those rays over a second, output, angular range, such that the output angular range is larger than the input angular range.

According to yet another embodiment of the present invention the micro-structure has a trough-like cross-section with oblong inner and outer faces substantially parallel to the photo-sensitive surface. The inner face and/or micro-structure exit (next to the photo-sensitive surface) of the micro-structure is adjacent (and preferably optically coupled and matched) to the photo-sensitive surface. The outer face and/or micro-structure entry is larger than the photo-sensitive area adjacent to one or more metal fingers to at least partially cover the adjacent metal fingers. In some embodiments of the present invention, the outer faces of adjacent micro-structures completely and/or substantially completely cover one or more metal fingers.

In some embodiments of the invention, the inner and outer faces are flat or substantially flat. In one example of the present invention, the side surfaces connecting the oblong faces may have a parabolic contour. In another example, the sides have a straight contour, resulting in, for example, truncated ‘V’ trough-like cross-sectional shape. In yet another example, the sides may have a parabolic contour, optionally over part of the distance between the faces and a straight contour over part of the distance. In yet other examples, the micro-structure may be fabricated with a 3D based shape to accommodate grid patterns other than grid patterns that include parallel strips as is described herein, for example, irregular grid patterns and/or crossed grids. Other suitable geometries which result in directing incident light to the photo-sensitive area may be used.

According to embodiments of the present invention, the micro-structure may be fabricated from glass, glassy sol-gels, sol-gels, and/or polymers. Other suitable materials may be used.

In various embodiments, fabrication methods may include, X-ray lithography (LIGA), photo-resist micro-stereo-lithography, deep-proton writing and two-photon polymerization. In other embodiments, the micro-structures may be mass produced by replication techniques, for example such as micro-injection molding and hot embossing and placed over the photo-sensitive area. Other suitable fabrication methods may be used.

According to an exemplary embodiment, the micro-structure may be an integral or fabricated part of an exit of a macro-concentrator. For example, the micro-structure may be an integral or fabricated part of the exit of a dielectric macro-concentrator, e.g. an all-dielectric macro-concentrator.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features and advantages thereof, may best be understood by reference to the following detailed description of non-limiting exemplary embodiments, when read with the accompanying drawings in which:

FIG. 1 is a schematic illustration of the solar cell system including at least one optical micro-structure according to an embodiment of the present invention;

FIG. 2 is a schematic isometric illustration of a micro-structure element according to an embodiment of the present invention;

FIG. 3 is a schematic illustration of the cross-section of a micro-structure according to an embodiment of the present invention;

FIGS. 4A and 4B are schematic cross-sectional illustrations of non-overlapping and overlapping contours respectively of micro-structures according to an embodiment of the present invention;

FIG. 5 is a schematic cross-sectional illustration of overlapping micro-structures according to an embodiment of the present invention; and

FIG. 6 is a graph of micro-structure Aspect Ratio (AR) as a function of Concentration (C) at prescribed micro-structure input angles θ₁ (and fixed output angle θ₂) according to embodiments of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF EXEMPLARY EMBODIMENTS

In the following description, exemplary embodiments of the invention incorporating various aspects of the present invention are described. For purposes of explanation, specific configurations and details are set forth in order to provide a thorough understanding of the embodiments. However, it will also be apparent to one skilled in the art that the present invention may be practiced without the specific details presented herein. Furthermore, well-known features may be omitted or simplified in order not to obscure the present invention. Features shown in one embodiment may be combined with features shown in other embodiments. Such features are not repeated for clarity of presentation.

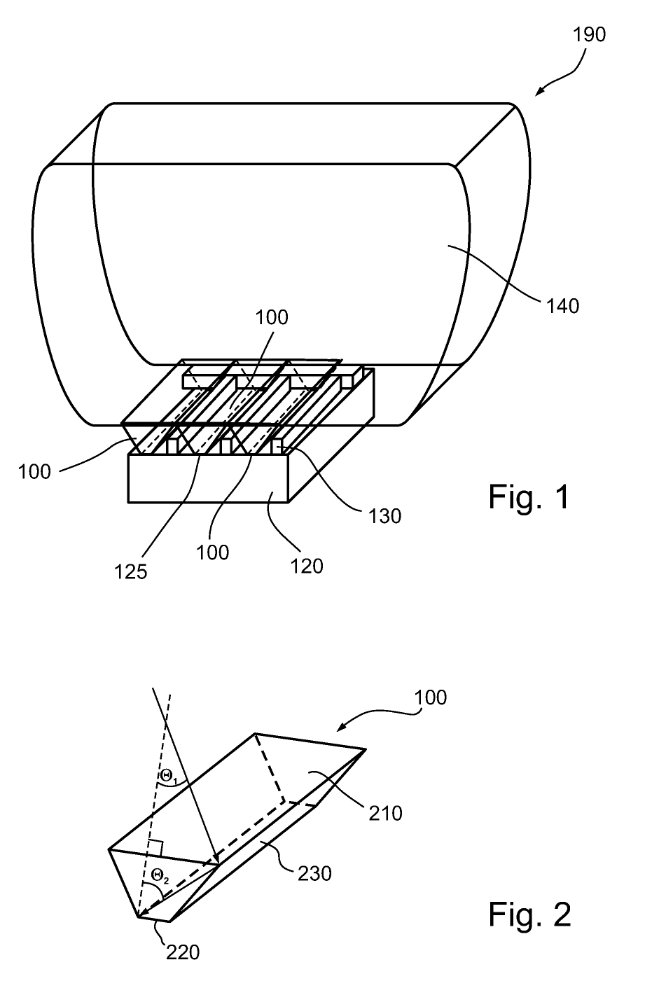

Reference is now made to FIG. 1 showing a schematic illustration of a concentrator solar cell system 190 including at least one optical micro-structure 100 according to embodiments of the present invention.

In various embodiments of the present invention one or more optical micro-structure element(s) 100 may be sandwiched between a light absorbing PV material 120 and a macro-concentrator 140 and optically coupled to both of them. Macro-concentrator 140 is schematic and not to scale and represents a generic macro-concentrator. Each optical micro-structure element 100 may be positioned between metal fingers 130 and may redirect impinging light directed toward the metal fingers and/or conductors 130, towards photo-sensitive areas 125, between metal fingers 130. In various embodiments, micro-structure 100 is a dielectric micro-concentrator, e.g. an all dielectric micro-concentrator. In some examples, micro-structure 100 is a non-imaging optical micro-structure.

In various embodiments of the invention, micro-structure 100 is positioned on the face of a solar cell, e.g. over photo-sensitive area 125 to redirect impinging light directed toward the metal fingers and/or conductors 130, towards photo-sensitive areas 125, e.g. photo-sensitive areas 125 between metal fingers 130. The micro-structure 100 includes a top surface through which impinging light is collected via the macro-concentrator 140 and a respective bottom surface that is structured to fit over a photo-sensitive area 125 between metal fingers 130, to which the collected light is directed. Optionally, structure 100 is tapered from a larger area above metal fingers 130, to a smaller area between metal fingers 130 and over photo-sensitive surface 125.

According to embodiments of the present invention, photo-sensitive area 125 may be coated with an anti-reflective coating and micro-structure 100 as well as macro-concentrator 140 may be fabricated from material, e.g. dielectric material and/or dielectric optical material, having an index of refraction (n) comparable to the n of the coating. Matching the n of the macro-structure 140 and the micro-structure 100 to the effective n of the coating may provide for substantially low reflective losses, e.g. losses substantially close to zero. This assertion may also apply to macro-concentrators that are not in contact with the micro-concentrator, e.g., a lens or a mirror-based optic, where light reaches the micro-concentrator from air rather than from the optically coupled exit of a dielectric macro-concentrator.

According to some embodiments of the present invention, macro-concentrator 140 may include two dimensional or three dimensional optical elements. Optionally, the macro-concentrator comprises reflective and/or refractive optical elements. Typically, entry of the macro-concentrator is larger than the solar cell area. Optionally, macro-concentrator 140 is not used and/or included.

An optimal metal grid coverage of concentrator solar cell surfaces may reflect the tradeoff between shading obscuration and the solar cell's series resistance Rₛ. Concentrator cells may exhibit low Rₛ, and their efficiency may peak as a function of concentration C, with, for example, a strong non-linear decrease at high flux that may be controlled by Rₛ. The fraction of active cell area covered by the metallization in known commercial concentrator cells may range, for example, between 10-16%. The micro-concentrator designs permit widening the metal fingers toward lessening series resistance losses, which can also finesse the need for the intricate metallization patterns of some high-flux solar cells.

Known metal fingers 130 may typically have a height in the order of 1 μm, e.g. a few μm and a width in the order of 10 μm. Known spacing between the metal fingers 130 may be roughly 0.1 mm independent of cell linear dimensions. Known metal grid patterns may typically include parallel strips of metal fingers 130. Alternately grid patterns may include irregular patterns, circular grids and/or crossed grids. Known cell linear dimensions may be of order 1 to 10 mm for concentrator solar cells.

Increasing the cell coverage in known systems may result in an increase of shadowing obscuration on the one hand while decreasing the cell coverage may increase Rₛ to undesirable levels on the other hand, both of which may contribute to a reduction in the efficiency of the solar cell.

Embodiments of the present invention provide the possibility of widening the metal fingers while eliminating shadowing losses by the metal grid and reducing series resistance losses. This may be facilitated by for example redistributing the elevated flux from available macro-concentrators, rather than, for example, increasing overall concentration.

Reference is now made to FIG. 2 showing micro-structure element 100 separate from the rest of the solar cell system 190, according to embodiments of the present invention. According to an embodiment of the present invention, the micro-structure has a trough-like cross-section with oblong faces 210 and 220 substantially parallel to the photo-sensitive surface 125 (FIG. 1) over which the micro-structure sits. Side surfaces 230 may be angled resulting in a tapered micro-structure that may partially or completely cover metal fingers 130 on its outer face 210 and fit between the metal fingers 130 on its inner face 220. Inner face 220 (next to photo-sensitive surface 125) of micro-structure element 100 is contiguous (and preferably optically coupled and refractive-index matched) to photo-sensitive surface 125. Outer face 210 is larger than photo-sensitive area 125, is contiguous to macro-concentrator 140 and is adjacent to one or more metal fingers 130 to at least partially cover the adjacent metal fingers 130. In examples of the present invention, outer faces 210 of adjacent micro-structures may completely and/or substantially completely cover (overlay) one or more metal fingers 130.

According to an embodiment of the present invention, light may enter and/or impinge onto the micro-structure 100 through the outer face 210 and exit the micro-structure through inner face 220. Since the width and the surface area of the inner face are smaller than that of the outer face, the impinging light is concentrated as it exits toward the photo-sensitive area 125.

According to some exemplary embodiments of the present invention, micro-structure 100 may be configured to accept all rays over a first input angular range ±θ₁, and concentrate those rays over a second larger output angular range ±θ₂, such that the output angular ±θ₂ range is larger than the input angular range ±θ₁. As such, micro-structure 100 may act as a concentrator to concentrate light rays impinging onto the outer face 210 that may initially be directed toward the neighboring metal fingers 130, toward the inner face 220 directed to photo-sensitive area 125.

According to one embodiment of the present invention, micro-structure 100 may be a non-imaging θ₁/θ₂ micro-concentrator predicated on total-internal-reflection (TIR) of side surfaces 230. In one example the micro-structure 100 may be a θ₁/θ₂ non-imaging transformer, which may accept all rays incident up to ±θ₁, and may concentrate them onto photo-sensitive surface 125 over angular range ±θ₂. In its full form, it may attain the corresponding thermodynamic limit to 2D flux concentration:

Cₘₐₓ=sin(θ₂)/sin(θ₁) (Equation 1)

which is also the ratio of entry to exit width with no ray rejection.

In exemplary embodiments of the present invention micro-structure 100 may be form that is not full form, e.g. cutoff version of the full form.

According to some exemplary embodiments of the present invention, micro-structure 100 may be fabricated from glass, glassy sol-gels, and/or polymers. Other suitable materials may be used.

In various embodiments, fabrication methods may include photo-resist, microlithography, X-ray lithography (LIGA), micro-stereo-lithography, deep-proton writing and two-photon polymerization. In other embodiments, micro-structure 100 may be mass produced by replication techniques, for example such as micro-injection molding and hot embossing and placed over the photo-sensitive area, preferably being bonded thereto. Other suitable fabrication methods may be used. In some examples side surfaces 230 of micro-structure 100 may be coated with, for example a reflective material, for example to increase the input angle.

Sample dimensions of a micro-structure 100 for a 1 mm² concentrator solar cell with parallel grid may include, for example, a 0.1 mm height (distance between outer and inner face 210 and 200 respectively, 0.1 mm² outer face surface area (with dimensions 0.1 min×1 mm)) and a 0.09 mm² inner face surface area (with dimensions 0.09 mm×1 mm). According to embodiments of the present invention, the dimensions of the micro-structures may be proportional to a specific grid size and solar cell dimensions and may be applicable to different solar cell linear dimensions, e.g., to 1 cm² or larger cells as well as to non-concentrator solar cells.

In an exemplary embodiment of the present invention, a series of micro-structures as depicted in FIG. 1 may be fabricated, for example, in one mold and/or as one unit. In another exemplary embodiment, a series of micro-structures as well as the macro-concentrator may be fabricated from a single mold and/or as a single unit.

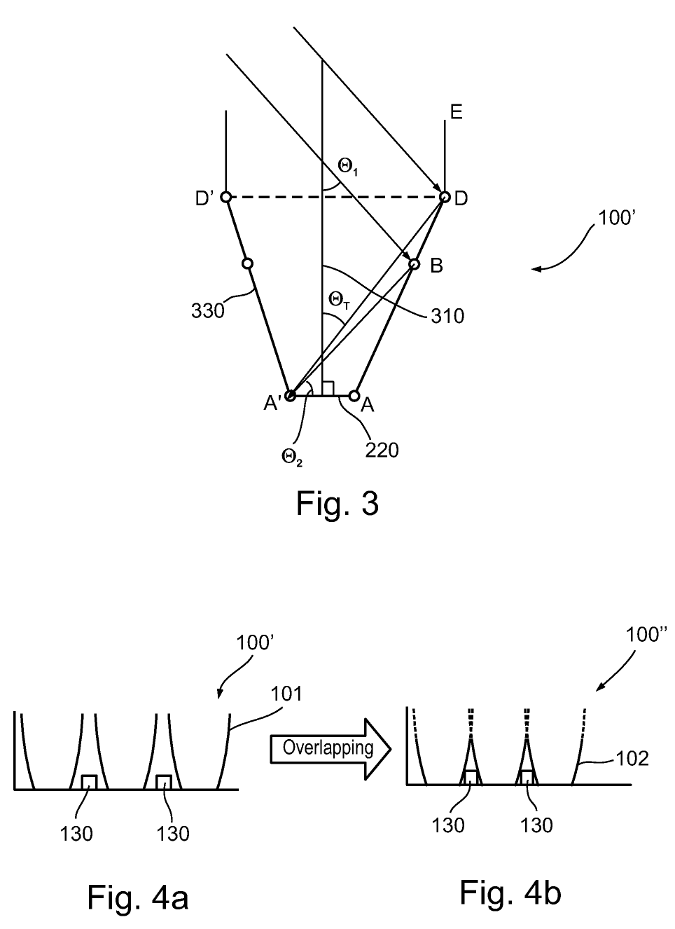

Reference is now made to FIG. 3 showing a side view of a cross section of a particular micro-structure element 100′ according to an embodiment of the invention. According to the embodiment shown a full side contour 330 of micro-structure 100′ may include a parabolic contour EDB, optionally over part of the distance between outer face 210 and inner face 220 and a straight contour BA over part of the distance. In one embodiment side contour 330 may include a lower contour, e.g. contour BA adjacent to the edge of the inner surface 220 and an upper contour, e.g. BDE adjacent to the edge of the outer surface 210.

According to some embodiments of the present invention, upper contour EDB may be an arc of a parabola with focus at A′ and axis rotated θ₁ relative to an optic axis 310. Lower section BA may be a straight line tilted at (θ₂−θ₁)/2.

According to embodiments of the present invention, the micro-structure may include sides with a full side contour EDBA. Although the full side contour EDBA may be ideal, many practical cases may not mandate maximum concentration, so the micro-structure may be cut off to facilitate more practical fabrication and assembly. According to some embodiments of the present invention, the side contours may be cut off at point B to include only the straight portion of contour EDBA. In other exemplary embodiments the side contour may be cut off at a point along the parabolic contour, e.g. point D. Other cutoffs may be implemented based on specific design requirements.

A cutoff to point D at angle θ_{T} or at point B may on the one hand reduce the micro-structures' depth providing for a more compact structure, but on the other hand may reduce the amount of concentration that the micro-structure may achieve. Sufficient cutoff of the side contour 330 may yield a pure straight contour. A cutoff to for example point B may result in a truncated V-trough contour.

Cutoff of the side-contour may provide for a more compact structure. In some examples, the cutoff may cut into to the linear section, e.g. contour BA, and micro-structure 100 may attain a V-trough shape, providing a structure geometry that is simple to fabricate. The V-trough is a cutoff version of a θ₁/θ₂ device and is therefore subsumed in the general analysis of side contour 330. Cutoff of micro-structure 100′ may facilitate a short optical path length so as to reduce absorption.

The micro-structure aspect ratio (AR) may be defined as depth/entry, where the depth may be defined as the distance between inner and outer face 220 and 210 respectively and the entry may be characterized by the surface area of outer face 210 through which the light impinges.

The expressions for the concentration C as functions of θ₁, θ₂ an θ_{T} may follow from straightforward geometry:

$$\begin{matrix}C = \{ \begin{matrix}\frac{2 ( sin ( {θ}_{1} ) + sin ( {θ}_{2} ) ) sin ( {θ}_{T} )}{1 - cos ( {θ}_{1} + {θ}_{T} )} - 1 & {θ}_{1} \leq {θ}_{T} \leq {θ}_{2} \\ \frac{tan ( {θ}_{T} ) + tan ( \frac{{θ}_{2} - {θ}_{1 }}{2} )}{tan ( {θ}_{T} ) - tan ( \frac{{θ}_{2} - {θ}_{1}}{2} )} & {θ}_{2} \leq {θ}_{T} \leq {90}^{∘}\end{matrix} & ( Equation 2 ) \\ AR = \{ \begin{matrix}\frac{( sin ( {θ}_{1} ) + sin ( {θ}_{2} ) ) cos ( {θ}_{T} )}{\begin{matrix}2 ( sin ( {θ}_{1} ) + sin ( {θ}_{2} ) ) sin ( {θ}_{T} ) \\ cos ( {θ}_{1} + {θ}_{T} ) - 1\end{matrix}} & {θ}_{1} \leq {θ}_{T} \leq {θ}_{2} \\ \frac{1}{tan ( \frac{{θ}_{2} - {θ}_{1}}{2} ) + tan ( {θ}_{T} )} & {θ}_{2} \leq {θ}_{T} \leq {90}^{∘}\end{matrix} & ( Equation 3 )\end{matrix}$$

Satisfying TIR for all incident rays may additionally require

θ₁+θ₂<180°−2θ_{c} (Equation 4)

where θ_{c}=Sin⁻¹(1/n) is the dielectric's critical angle. In one example θ₂ may be bounded to achieve substantially negligible (e.g., <1%) Fresnel reflective losses between the micro-concentrator and the solar cell surface. Other ranges of Fresnel reflective losses may be used. For example, θ₂ may be approximately 55° based on, for example, measurements for known types of concentrator cells with anti-reflective coatings. In one example, TIR may be satisfied for substantially the entire parameter space considered herein (θ₁ up to ≈30°, θ₂ up to ≈55° and n=1.5). Other examples may be implemented with other ranges of Fresnel reflective losses, input and output angles, and n.

Reference is now made to FIGS. 4A and 4B showing a schematic illustration of non-overlapping contours 101 and overlapping contours 102 of micro-structures 100′ and 100″ respectively according to exemplary embodiments of the present invention. Metal fingers 130 may sit between the micro-structures. Typically, fabrication tolerances may militate against a perfect match of adjoining micro-structures. According to embodiments of the present invention, the micro-structures may be designed for overlapping contours and the micro-structures may be fabricated in their cutoff form. (FIG. 4B)

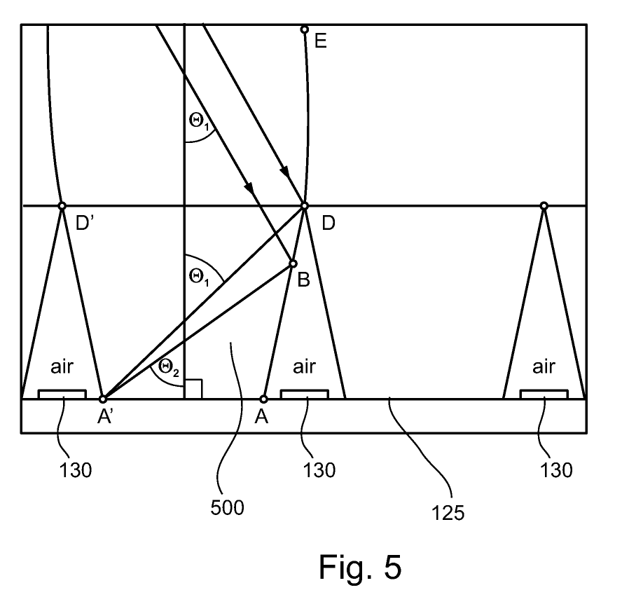

Reference is now made to FIG. 5 which is a schematic cross-sectional illustration of overlapping micro-structures according to an embodiment of the present invention. According to embodiments of the present invention upper contour EDB may be the arc of a parabola with focus at A′ and axis rotated θ₁ relative to the optic axis. Lower section BA may be a straight line tilted at (θ₂−θ₁)/2. Cutoff to point D at angle θ_{T} may reduce device depth as well as concentration. The dielectric region 500, and the metal fingers 130 in contact with the photo-sensitive area 125 and/or solar cell surface fit comfortably between adjacent troughs. In one example, the cutoff micro-structure may have an entry D′D (˜100 μm), θ₁=30°, θ₂=55° and θ_{T}=46°, with C=1.50 and AR=0.80. Other entry lengths and or angles may be implemented.

The concentrator solar cell residing at the exit of a macro-concentrator may typically have an acceptance half-angle of ≈0.005-0.030 radian, deployed on a dual-axis solar tracker. According to some embodiments of the present invention, the far larger exit half-angle θ₁ of light concentrated by the macro-concentrator (often as low as, but not restricted to, ≈15-30°) becomes the input design angle for the dielectric micro-concentrators 100. Such seemingly low θ₁ values may still be sufficient for achieving the net flux levels of hundreds (even up to 2000) suns at which the efficiency of the most efficient concentrator cells peaks.

Embodiments of the present invention relate to the most common metal grid pattern of parallel strips. The geometry of the micro-structure 100 as described in FIG. 2 and herein may be suitable for metal grid patterns of parallel strips. Other metal grid patterns are available and micro-structure 100 may be tailored for the different metal grid patterns available. For example, micro-structure 100 that may eliminate metallization shadowing can also be tailored to irregular elaborate grids that were developed to maintain acceptably low Rₛ without raising metal coverage. The corresponding 3D micro-structures would require more complex fabrication procedures, but may be achieved. However, such complex metallization schemes may alternatively be replaced by simpler less expensive parallel-strip grids with one or more micro-structure(s) 100, because the associated greater metal coverage may reduce Rₛ to a level that could formerly only be attained with irregular intricate grid patterns.

In one example, the lowest concentration C of interest may be approximately 1.1, for an effective metallization coverage of approximately 10% (uncorrected for production tolerances as noted herein), with substantially no change in metal finger width. Concentration may be increased when the metal fingers 130 are widened (so the gridline spacing is lessened), to a coverage ratio of 1-(1/C) (with C bounded by Eq (1)).

In some examples, the width of the metal fingers 130, typically in the order of magnitude of approximately 10 μm for concentrator solar cells, may be increased, for example, without changing the height of the metal fingers 130. Convolving reasonable production tolerances and alignments with the actual width of the metal fingers 130 may increase the equivalent finger width for which designs may be generated, for example by approximately 20% while eliminating shadowing due to metallization. Other ranges of increases in equivalent finger widths may be possible.

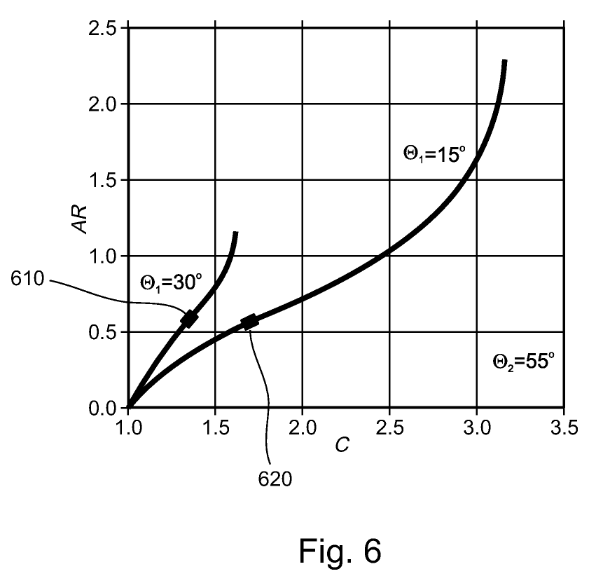

Reference is now made to FIG. 6 showing a graph of micro-structure AR as a function of C at prescribed micro-structure input angles θ₁ and fixed output angle θ₂ according to embodiments of the present invention. According to embodiments of the present invention, θ₁ may be determined based on the properties of the macro-concentrator 140. Parameters C and θ₂ may be determined based on the design of the micro-structure 100. In some embodiments of the present invention, a low AR, with V-troughs may be desired. Representative results are plotted in FIG. 6, a range of which includes ultra-compact V-troughs. The micro-structure AR as a function of C at prescribed θ₁, at the maximum θ₂=55° is shown. As C is decreased from its maximum value by cutoff, a point 610 and/or point 620 is reached below which the micro-structure 100 is a substantially pure V-trough.

For known concentrator solar cells, e.g. commercially available triple junction square concentrator solar cells, the micro-structure 100 described herein may offer an optical efficiency boost of approximately 10-12% (relative) by substantially obviating metallization shadowing. The micro-structure may create the added benefit of reduced gridline spacing as described herein, and hence reduced Rₛ. This may also increase the maximum efficiency, e.g. increase of approximately 7% of the solar cell system which may improve with the concentration of the macro-concentrators above 500 suns. The same magnitude of efficiency improvement deriving solely from the reduced Rₛ achieved with optimized flux redistribution has been demonstrated for line-focus concentrator cells tailored to flux levels of tens of suns.

Marked flux inhomogeneities may usually translate into lowered efficiency compared to uniform cell irradiation. However, for high-efficiency photovoltaics, (1) when micro-concentrator C is approximately 1.1, the effect may be substantially zero, and (2) even at the highest C values evaluated above, experimental results indicate a negligible efficiency reduction from the attendant stronger flux non-uniformity.

The solar cell optical system described herein may substantially reduce and/or eliminate front contact shading losses.

The micro-structure 100 described herein may be a non-imaging micro-concentrator that may exploit TIR to redistribute the elevated flux from available macro-concentrators, rather than increasing overall concentration. Flexibility in the design strategy may allow the metal fingers 130 to be widened toward also reducing series resistance (Rₛ) losses. Net efficiency gains may be increased in a wide variety of concentrating PV devices.

It is noted herein that although embodiments of the present invention may have been described in reference to concentrator solar cells, the present invention may be equally applied to non-concentrator solar cells and low concentration solar cells, where the width of the metal grid fingers may be in the order of approximately a millimeter and the spacing between metal fingers is may be greater than the small distances encountered in concentrator solar cells. According to embodiments of the present invention, the device, system and method described herein facilitates eliminating shadowing loss resulting metallization grid in non-concentrator solar cells and low concentration solar cells as well as reducing their solar cell series resistance by permitting wider and more closely spaced metal grid.

It is also noted that the device, system and method described herein may be applied to bifacial solar cells, e.g. concentrator and non-concentrator bifacial cells, with the potential added value of lessening the asymmetry in conversion efficiency between the front and back sides of the cell thereby improving overall cell efficiency.

It should be further understood that the individual features described herein above can be combined in all possible combinations and sub-combinations to produce exemplary embodiments of the invention. The examples given above are exemplary in nature and are not intended to limit the scope of the invention which is defined solely by the following claims. Specifically, the invention has been described in the context of a left atrium but might also be used in a right atrium or a ventricle.

The terms “include”, “comprise” and “have” and their conjugates as used herein mean “including but not necessarily limited to”.

1. A solar cell system comprising:
a solar cell comprising a grid and a photo-sensitive area, wherein the grid includes a conductor; and
an optical micro-structure positioned between the conductors, wherein the micro-structure covers at least a portion of the conductors.

2. The solar cell system according to claim 1 wherein the optical micro-structure comprises:
an inner face optically coupled to the photo-sensitive area; and
an outer face configured to receive light.

3. The solar cell system according to claim 2 comprising a macro-concentrator configured to concentrate light onto the solar cell.

4. The solar cell system according to claim 3 wherein the outer face receives light via the macro-concentrator.

5. The solar cell system according to claim 3, wherein the optical micro-structure is optically coupled to the macro-concentrator.

6. The solar cell system according to claim 3, wherein the optical micro-structure is sandwiched between the solar cell and the macro-concentrator.

7. The solar cell system according to claim 2, wherein the inner and outer faces are substantially parallel to each other.

8. The solar cell system according to claim 1 comprising an anti-reflective coating on the photo-sensitive area.

9. The solar cell system according to claim 1, wherein the grid is a parallel metal grid.

10. The solar cell system according to claim 9 wherein the inner and outer faces are oblong faces.

11. The solar cell system according to claim 1, wherein the micro-structure comprises a trough-like cross-section.

12. The solar cell system according to claim 11 wherein the trough-like cross-section is a V-trough.

13. The solar cell system according to claim 11 wherein the inner face has a surface area that is smaller than the surface area of the outer face and wherein light impinges the micro-structure through the outer face and exits the micro-structure through the inner face.

14. The solar cell system according to claim 11, wherein the micro-structure is configured to accept rays from a macro-concentrator over a first input angular range and concentrates the rays over a second output angular range, wherein the output angular range is larger than the input angular range.

15. The solar cell system according to claim 2, wherein rays over an input angular range impinge onto the micro-structures through the outer face and the light rays over an output angular range exit the micro-structures through the inner face, wherein the input angular range is smaller than the output angular range.

16. The solar cell system according to claim 2, wherein the micro-structures include side surfaces connecting the inner and outer faces, wherein the side surfaces have a straight tilted contour.

17. The solar cell system according to claim 2, wherein the micro-structures include side surfaces connecting the inner and outer faces, wherein the side surfaces have a parabolic contour over a first part of a distance between the inner and outer faces and a straight tilted contour over a second part of the distance.

18. The solar cell system according to claim 16, wherein the straight tilted contour is tilted at an angle equaling half the difference between an input angle and an output angle, wherein the input angle is a maximum angle at which light rays impinge onto the outer face and the output angle is the maximum angle at which the light rays exit the inner face of the micro-structure.

19. The solar cell system according to claim 16, wherein the side surfaces of the micro-structure are configured for total internal reflection.

20. The solar cell system according to claim 1, wherein the micro-structure is fabricated from glass.

21. The solar cell system according to claim 1, wherein the micro-structure is fabricated from a polymer.

22. The solar cell system according to claim 3, wherein the micro-structure is fabricated from a material having an index of refraction comparable to an index of refraction of the macro-concentrator.

23. The solar cell system according to claim 1, wherein the micro-structure is fabricated by micro-injection molding.

24. The solar cell system according to claim 1, wherein the micro-structure is fabricated by hot embossing.

25. The solar cell system according to claim 1, wherein a plurality of micro-structures are fabricated as a single unit.

26. The solar cell system according to claim 3, wherein the micro-structure is an integral part of an exit of the macro-concentrator.

27. The solar cell system according to claim 3, wherein the macro-concentrator includes a lens.

28. The solar cell system according to claim 3, wherein the macro-concentrator includes a mirror.

29. The solar cell system according to claim 3, wherein the macro-concentrator includes dielectric optics.

30. The solar cell system according to claim 3, wherein the macro-concentrator is in physical contact with the micro-structure.

31. The solar cell system according to claim 2, comprising an anti-reflective coating on the outer face of the micro-structure.
